(19) United States
(12) Patent Application Publication
(10) Pub. No.: US 2026/0123435 A1
(43) Pub. Date: Apr. 30, 2026

(54) WIRING SUBSTRATE AND SEMICONDUCTOR DEVICE

(71) Applicant: SHINKO ELECTRIC INDUSTRIES CO., LTD., Nagano (JP)

(72) Inventor: Kohei OIDA, Nagano (JP)

(21) Appl. No.: 19/368,343

(22) Filed: Oct. 24, 2025

(30) Foreign Application Priority Data
Oct. 29, 2024 (JP) 2024-189466

(51) Int. Cl. H01L 23/00; H01L 23/498; H01L 23/544

(52) U.S. Cl. CPC H10W 42/121; H10W 90/701; H10W 46/00; H10W 46/301

(57) ABSTRACT

A wiring substrate includes a wiring layer, an insulating layer over the wiring layer, and a dam member on the insulating layer. The dam member has a frame shape. The dam member contains resin and filler dispersed in the resin. The dam member includes a first region contacting the insulating layer and a second region on the first region. The volume fraction of the resin in the first region is higher than the volume fraction of the resin in the second region.

### CROSS-REFERENCE TO RELATED APPLICATION

This application is based upon and claims priority to Japanese Patent Application No. 2024-189466, filed on Oct. 29, 2024, the entire contents of which are incorporated herein by reference.

### FIELD

A certain aspect of the embodiments discussed herein is related to wiring substrates and semiconductor devices.

### BACKGROUND

Some semiconductor devices have an electronic component mounted on a wiring substrate and have an underfill provided between the wiring substrate and the electronic component. To provide the underfill, fluid underfill is poured. The fluid underfill, however, may flow out to areas where the underfill is unnecessary. Therefore, a wiring substrate that includes a dam member that surrounds an area for mounting an electronic component to prevent fluid underfill from flowing out is proposed. (See Japanese Laid-open Patent Publication No. 2023-67260.)

### SUMMARY

According to an aspect, a wiring substrate includes a wiring layer, an insulating layer over the wiring layer, and a dam member on the insulating layer. The dam member has a frame shape. The dam member contains resin and filler dispersed in the resin. The dam member includes a first region contacting the insulating layer and a second region on the first region. The volume fraction of the resin in the first region is higher than the volume fraction of the resin in the second region.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIGS. 1A and 1B are diagrams illustrating a wiring substrate according to a first embodiment;

FIG. 2 is a sectional view of part of the wiring substrate, illustrating a dam member;

FIGS. 3A through 3D are sectional views illustrating a method of manufacturing a wiring substrate according to the first embodiment;

FIG. 4 is a sectional view illustrating a filler-containing layer subjected to planarization pressing;

FIGS. 5A and 5B illustrate cross-sectional scanning electron microscope (SEM) images;

FIG. 6 is a sectional view of a semiconductor device according to a second embodiment; and

FIGS. 7A and 7B are sectional views illustrating a method of manufacturing a semiconductor device according to the second embodiment.

### DESCRIPTION OF EMBODIMENTS

In recent years, there has been a growing demand for increasing the adhesion between an insulating layer such as a solder resist layer and a dam member included in a wiring substrate.

According to an aspect, the adhesion between an insulating layer and a dam member is increased. According to an embodiment, a wiring substrate and a semiconductor device that increase the adhesion between an insulating layer and a dam member are provided.

One or more embodiments of the present invention are explained with reference to the accompanying drawings. In the following description, the elements or components that have substantially the same functional configuration are referred to using the same reference numerals and duplicate description thereof may be omitted.

### [a] First Embodiment

A first embodiment is described. The first embodiment relates to a wiring substrate.

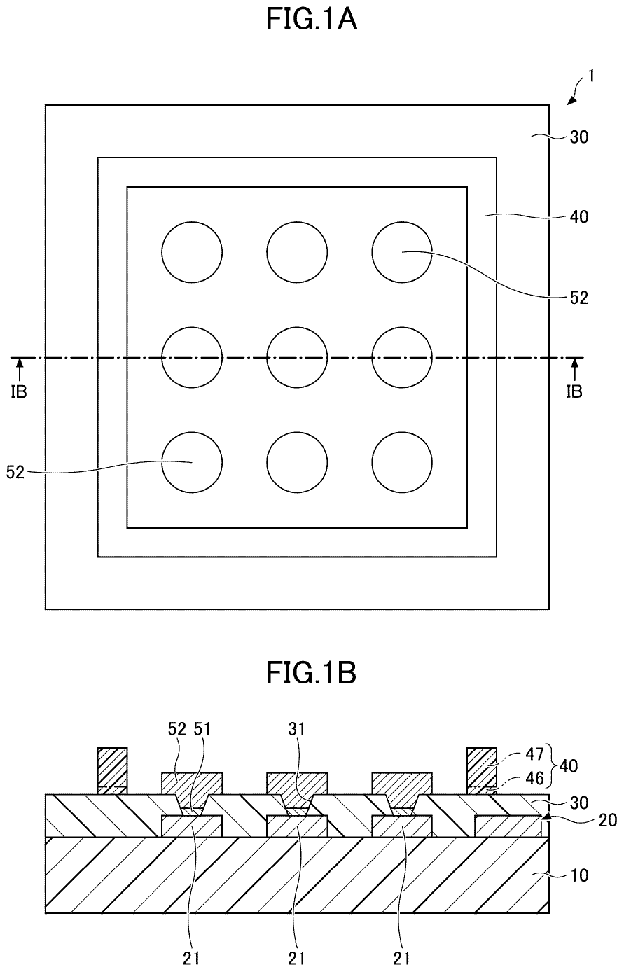

A structure of a wiring substrate according to a first embodiment is described. FIGS. 1A and 1B are diagrams illustrating a wiring substrate 1 according to the first embodiment. FIG. 1A is a plan view of the wiring substrate 1. FIG. 1B is a sectional view of the wiring substrate 1 taken along the line IB-IB of FIG. 1A.

The wiring substrate 1 is, for example, a build-up substrate. As illustrated in FIGS. 1A and 1B, the wiring substrate 1 includes a substrate 10, a wiring layer 20, a solder resist layer 30, a dam member 40, a barrier layer 51, and connection bumps 52.

The substrate 10 is, for example, a resin substrate that includes multiple wiring layers (not depicted) and multiple insulating resin layers (not depicted). The substrate 10 may either include or not include a core layer.

The wiring layer 20 is provided on a first surface (or upper surface) of the substrate 10. The wiring layer 20 is electrically connected to the wiring layers in the substrate 10. The wiring layer 20 includes electrode pads 21. The wiring layer 20 include, for example, copper (Cu).

According to this embodiment, for convenience, with respect to each part or component of the wiring substrate 1, a surface facing the same direction as the first surface of the substrate 10 is referred to as “first surface” or “upper surface”, and a surface facing away from the first surface is referred to as “second surface” or “lower surface”. Furthermore, the side of the first surface is referred to as “first side” or “upper side”, and the side of the second surface is referred to as “second side” or “lower side”. The wiring substrate 1, however, may be used in an inverted position or oriented at any angle. Furthermore, a plan view refers to a view of an object in a direction normal to the first surface of the substrate 10, and a planar shape refers to the shape of an object as viewed in a direction normal to the first surface of the substrate 10.

The solder resist layer 30 is formed on the first surface of the substrate 10 to cover the wiring layer 20. Openings 31 are formed in the solder resist layer 30. The openings 31 pierce through the solder resist layer 30. The openings 31 lie (are contained) within the corresponding electrode pads 21 in a plan view, and reach the corresponding electrode pads 21. The electrode pads 21 are part of the wiring layer 20. The solder resist layer 30 is an example of an insulating layer.

The barrier layer 51 is provided on the first surfaces of the electrode pads 21 in the openings 31. The connection bumps 52 are provided on the barrier layer 51 and the solder resist layer 30. The connection bumps 52 have respective portions in the openings 31 to be electrically connected to the corresponding electrode pads 21 of the wiring layer 20. The barrier layer 51 includes, for example, a nickel (Ni) plating layer, a palladium (Pd) plating layer, and a gold (Au) layer that are formed (stacked) in this order from the electrode pad 21 side. The connection bumps 52 include, for example, copper.

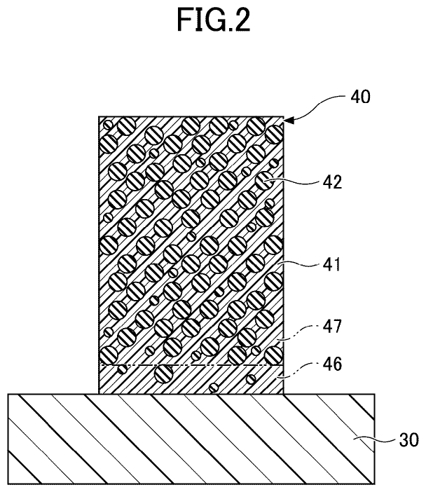

The dam member 40 is provided on the solder resist layer 30. The thickness of the dam member 40 is, for example, approximately 10 μm to approximately 50 μm, preferably approximately 15 μm to approximately 40 μm, and more preferably approximately 20 μm to approximately 30 μm. The dam member 40 has a frame shape in a plan view. In a plan view, the openings 31, the barrier layer 51, and the connection bumps 52 are positioned within (inside) the dam member 40. FIG. 2 is a sectional view of part of the wiring substrate 1, illustrating the dam member 40. As illustrated in FIG. 2, the dam member 40 contains resin 41 and filler 42. The filler 42 is dispersed in the resin 41. Examples of the resin 41 include epoxy resin, polyimide resin, and acrylic resin. The resin 41 may contain two or more of these resins. Examples of the filler 42 include silica (SiO₂). The particle size of the filler 42 is, for example, approximately 3 μm to approximately 4 μm. The mass of the filler 42 accounts for, for example, approximately 30% to approximately 70% of the mass of the dam member 40. The dam member 40 has a first region 46 and a second region 47. The first region 46 is in direct contact with the solder resist layer 30. The second region 47 is positioned over the first region 46. The first region 46 is positioned between the solder resist layer 30 and the second region 47. The volume fraction of the resin 41 in the dam member 40 is higher in the first region 46 than in the second region 47.

As described below, an electronic component is to be mounted in an area within (surrounded by) the dam member 40 in a plan view, and an underfill is to be provided between the electronic component and the solder resist layer 30. In this case, uncured fluid underfill is held back inside the dam member 40.

According to the wiring substrate 1, the dam member 40 includes the first region 46 and the second region 47, and the volume fraction of the resin 41 in the dam member 40 is higher in the first region 46 than in the second region 47. This makes it possible to improve the adhesion between the dam member 40 and the solder resist layer 30.

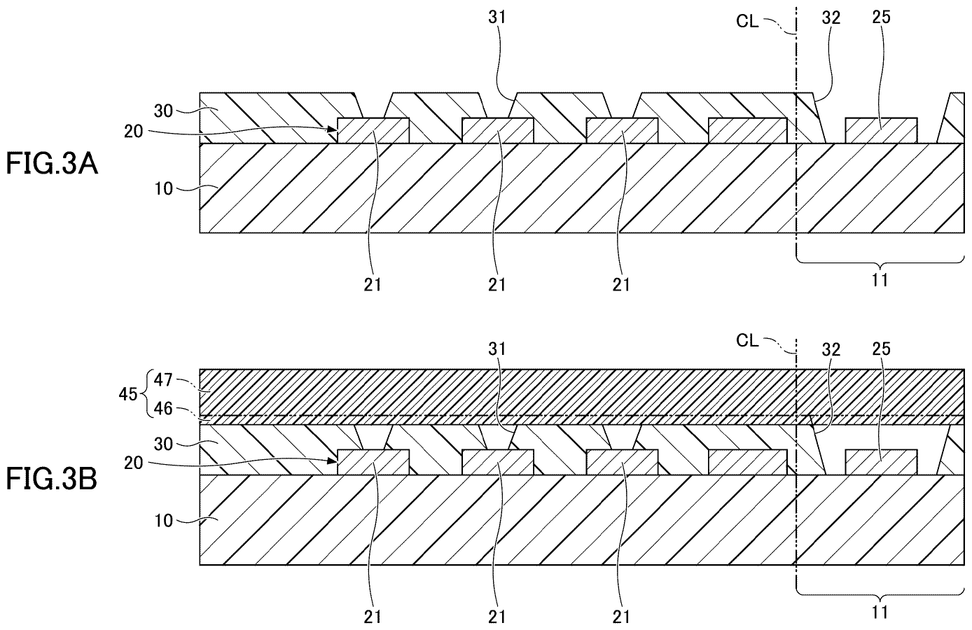

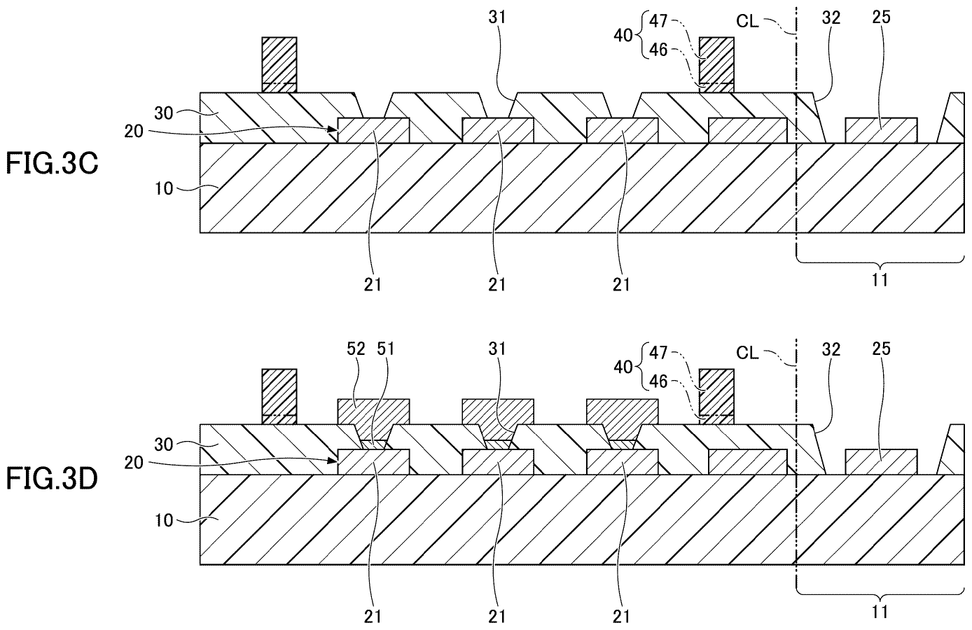

Next, a method of manufacturing a wiring substrate according to the first embodiment is described. FIGS. 3A through 3D are sectional views illustrating a method of manufacturing a wiring substrate according to the first embodiment.

First, as illustrated in FIG. 3A, the wiring layer 20 and the solder resist layer 30 are formed on the first surface of the substrate 10.

A large substrate that yields multiple wiring substrates 1 is used as the substrate 10. That is, the substrate 10 has multiple areas in each of which a structure corresponding to the wiring substrate 1 is formed. After manufacturing members to become wiring substrates 1 simultaneously, cutting is performed along scribe lines CL to separate the members into individual wiring substrates 1. For convenience of description, parts that finally become constituent elements of the wiring substrate 1 are referred to using the reference numerals of the constituent elements.

The substrate 10 has a cut region 11 that is cut off during singulation. When the wiring layer 20 is formed, the electrode pads 21 and an alignment mark 25 in the cut region 11 are included in the wiring layer 20. Furthermore, the openings 31 and an opening 32 that exposes the alignment mark 25 in the cut region 11 are formed in the solder resist layer 30. To form the solder resist layer 30, for example, a photosensitive layer containing filler to become the solder resist layer 30 is attached by vacuum lamination and is subjected to planarization pressing, and is thereafter exposed to light and developed. After the formation of the openings 31 and the opening 32, a process to remove native oxide present on the surfaces of the electrode pads 21 and the alignment mark 25 may be performed.

Next, as illustrated in FIG. 3B, a layer containing filler (“filler-containing layer”) 45 is provided on the solder resist layer 30. The filler-containing layer 45, which later becomes the dam member 40, contains the resin 41 and the filler 42 (see FIG. 2). At this stage, the resin 41 has photosensitivity. The filler-containing layer 45 may be provided by vacuum lamination. For example, the temperature of the substrate 10 is approximately 60° C. to approximately 90° C. when the filler-containing layer 45 is provided, and the filler-containing layer 45 is attached to the solder resist layer 30 with a pressure of approximately 0.3 MPa to approximately 2 MPa. The filler-containing layer 45 provided on the solder resist layer 30 by vacuum lamination has the first region 46 and the second region 47 because the resin 41 flows toward the solder resist layer 30 because of lamination pressure. The openings 31 and the opening 32 are not filled with the filler-containing layer 45, and gaps remain inside.

Thereafter, as illustrated in FIG. 3C, the filler-containing layer 45 having the first region 46 and the second region 47 is processed into the frame-shaped dam member 40. To process the filler-containing layer 45, alignment with reference to the alignment mark 25 is performed while viewing and checking the position of the alignment mark 25 through the filler-containing layer 45, and the filler-containing layer 45 is exposed to light and is thereafter developed.

Next, as illustrated in FIG. 3D, the barrier layer 51 is formed on the first surfaces of the electrode pads 21 in the openings 31, and the connection bumps 52 are formed on the barrier layer 51.

Next, the structure illustrated in FIG. 3D is cut along the scribe line CL. As a result, the cut region 11 and the alignment mark 25 and the solder resist layer 30 on the cut region 11 are cut off. In this manner, the wiring substrate 1 can be manufactured.

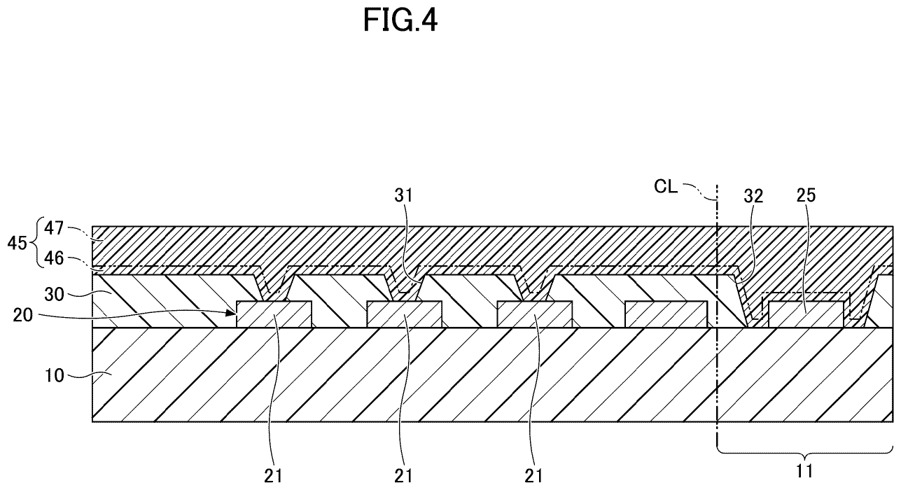

It is also possible to consider subjecting the filler-containing layer 45 to planarization pressing before processing the filler-containing layer 45 into the frame-shaped dam member 40 after providing the filler-containing layer 45 by vacuum lamination. Performing planarization pressing under normal conditions, however, disperses the filler 42 in the entirety of the filler-containing layer 45 to cause the first region 46 to disappear from the filler-containing layer 45. This prevents improvement in the adhesion between the dam member 40 and the solder resist layer 30. Furthermore, performing planarization pressing under normal conditions moves the filler-containing layer 45 into the opening 32 as illustrated in FIG. 4. Therefore, the thickness of the filler-containing layer 45 increases over the alignment mark 25 as well. Accordingly, depending on the thickness of the filler-containing layer 45, the visibility of the alignment mark 25 may decrease to prevent the position of the alignment mark 25 from being confirmed. Thus, it is preferable not to perform planarization pressing on the filler-containing layer 45. The filler-containing layer 45 may be subjected to planarization pressing only to the extent that the first region 46 and the second region 47 remain in the filler-containing layer 45 in order to improve the adhesion. FIG. 4 is a sectional view illustrating the filler-containing layer 45 subjected to planarization pressing.

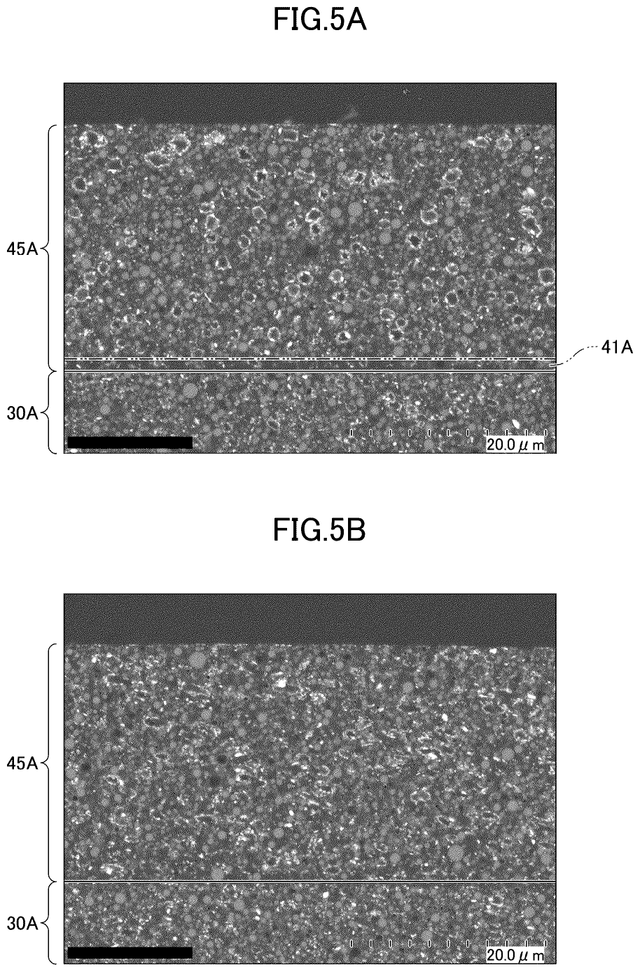

FIGS. 5A and 5B illustrate cross-sectional scanning electron microscope (SEM) images. FIG. 5A illustrates a cross-sectional SEM image of a sample subjected to no planarization pressing after a filler-containing layer 45A was attached onto a solder resist layer 30A by vacuum lamination. FIG. 5B is a cross-sectional SEM image of a sample subjected to planarization pressing after the filler-containing layer 45A was attached onto the solder resist layer 30A by vacuum lamination. According to the sample subjected to no planarization pressing, as illustrated in FIG. 5A, a region 41A where the volume fraction of filler is lower is present near the interface with the solder resist layer 30A in the filler-containing layer 45A. In contrast, according to the sample subjected to planarization pressing, as illustrated in FIG. 5B, filler is substantially uniformly dispersed in the filler-containing layer 45A and no region where the volume fraction of filler is lower is present near the interface with the solder resist layer 30A in the filler-containing layer 45A.

For example, the ratio of the volume fraction of the filler 42 in the first region 46 to the volume fraction of the filler 42 in the second region 47 is 60% or less. If this ratio is higher than 60%, the adhesion improvement effect due to the first region 46 may be reduced. This ratio is preferably 50% or less, and more preferably, 40% or less.

For example, the thickness of the first region 46 is 1 μm or more and 3 μm or less. When the thickness of the first region 46 is less than 1 μm, the adhesion improvement effect due to the first region 46 may be reduced. If the thickness of the first region 46 is more than 3 μm, the strength of the dam member 40 may be reduced. The thickness of the first region 46 is preferably 1 μm or more and 2.5 μm or less, and more preferably, 1 μm or more and 2 μm or less.

The comparative relationship between the volume fraction of the filler 42 in the first region 46 and the volume fraction of the filler 42 in the second region 47 may be substituted by the comparative relationship between the area fraction of the filler 42 in the first region 46 and the area fraction of the filler 42 in the second region 47 as observed in cross section. The volume fraction ratio may be calculated by raising the area fraction ratio to the power of 3/2. For example, when the ratio of the area fraction of the filler 42 in the first region 46 to the area fraction of the filler 42 in the second region 47 is 64%, the ratio of the volume fraction of the filler 42 in the first region 46 to the volume fraction of the filler 42 in the second region 47 is calculated to be 51.2%.

### [b] Second Embodiment

A second embodiment is described. The second embodiment relates a semiconductor device including the wiring substrate 1 according to the first embodiment.

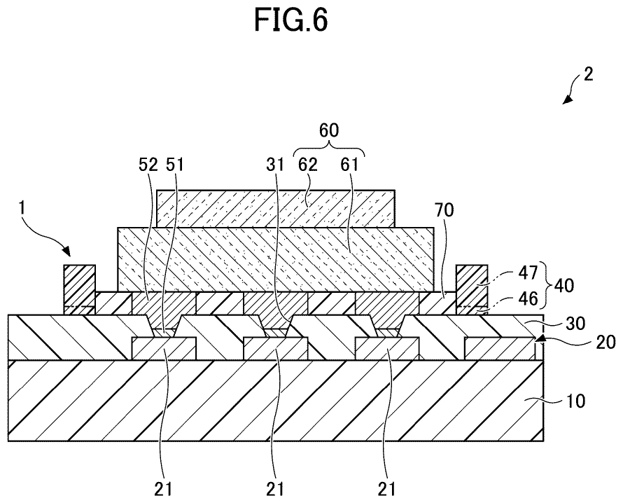

A structure of a semiconductor device according to the second embodiment is described. FIG. 6 is a sectional view of a semiconductor device according to the second embodiment.

Referring to FIG. 6, a semiconductor device 2 according to the second embodiment includes the wiring substrate 1, an electronic component 60, and an underfill 70.

The electronic component 60 is electrically connected to the connection bumps 52. The electronic component 60 includes an interposer 61 and a die 62. The interposer 61 is, for example, a silicon (Si) interposer. The interposer 61 may be an interposer using resin. The interposer 61 includes electrodes bonded to the connection bumps 52 using solder or the like, for example. The die 62, which is, for example, a semiconductor chip, is mounted on the interposer 61.

The underfill 70 is provided between the solder resist layer 30 and the electronic component 60. The underfill 70 covers the respective side surfaces of the connection bumps 52 to protect the connection bumps 52. The underfill 70 includes, for example, epoxy resin.

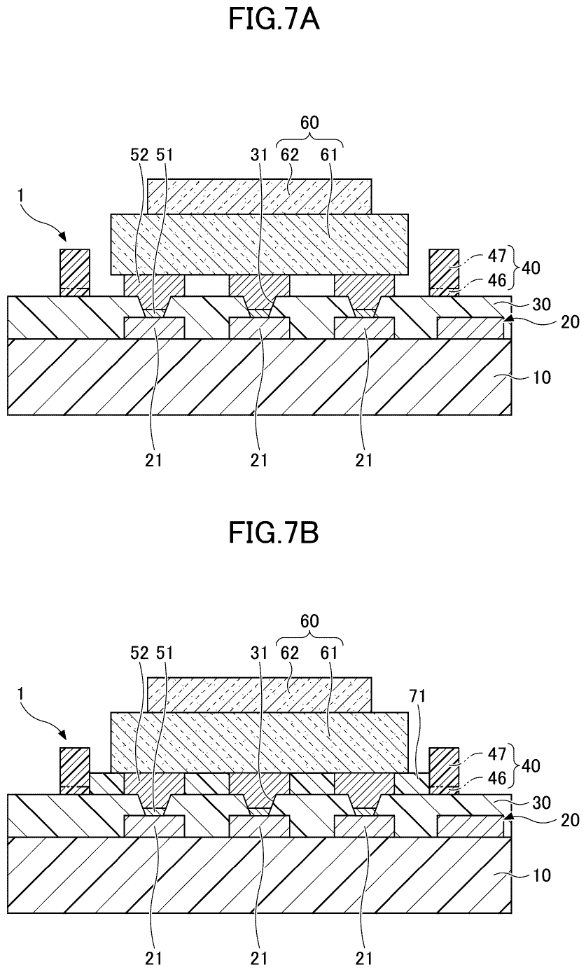

Next, a method of manufacturing a semiconductor device according to the second embodiment is described. FIGS. 7A and 7B are sectional views illustrating a method of manufacturing a semiconductor device according to the second embodiment.

First, as illustrated in FIG. 7A, the wiring substrate 1 is prepared, and the electronic component 60 is mounted on the wiring substrate 1. At this point, electrodes of the interposer 61 are bonded to the connection bumps 52 using solder or the like, for example.

Next, as illustrated in FIG. 7B, uncured fluid underfill 71 is poured into the space between the electronic component 60 and the solder resist layer 30. Because the dam member 40 is provided on the solder resist layer 30, the underfill 71 is held back inside the dam member 40.

Thereafter, the underfill 71 is cured into the underfill 70 (see FIG. 6). The respective side surfaces of the connection bumps 52 are covered with the underfill 70, so that the connection bumps 52 are protected by the underfill 70.

The semiconductor device 2 may be manufactured in this manner.

The electronic component 60 does not have to include the interposer 61, and a semiconductor chip may be flip-chip bonded to the connection bumps 52.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

Various aspects of the subject-matter described herein may be set out non-exhaustively in the following numbered clauses:

1. A method of manufacturing a wiring substrate, the method including:
forming an insulating layer over a wiring layer;
providing a filler-containing layer on the insulating layer by vacuum lamination, the filler-containing layer containing resin and filler dispersed in the resin; and
   processing the filler-containing layer into a dam member having a frame shape,
   wherein the filler-containing layer includes a first region contacting the insulating layer and a second region on the first region,
   a volume fraction of the resin in the first region is higher than a volume fraction of the resin in the second region, and
   the filler-containing layer is processed into the dam member with the first region and the second region being included in the filler-containing layer.

2. The method of clause 1, wherein processing the filler-containing layer includes exposing to light and developing the filler-containing layer.

3. The method of clause 1, wherein no planarization pressing is performed on the filler-containing layer between providing the filler-containing layer and processing the filler-containing layer.

What is claimed is:

1. A wiring substrate comprising:
a wiring layer;
an insulating layer over the wiring layer; and
a dam member on the insulating layer, the dam member having a frame shape, the dam member containing resin and filler dispersed in the resin,
the dam member including
a first region contacting the insulating layer; and
a second region on the first region,
wherein a volume fraction of the resin in the first region is higher than a volume fraction of the resin in the second region.

2. The wiring substrate as claimed in claim 1, wherein a ratio of a volume fraction of the filler in the first region to a volume fraction of the filler in the second region is 60% or less.

3. The wiring substrate as claimed in claim 2, wherein the ratio of the volume fraction of the filler in the first region to the volume fraction of the filler in the second region is 50% or less.

4. The wiring substrate as claimed in claim 3, wherein the ratio of the volume fraction of the filler in the first region to the volume fraction of the filler in the second region is 40% or less.

5. The wiring substrate as claimed in claim 1, wherein a thickness of the first region is 1 μm or more and 3 μm or less.

6. The wiring substrate as claimed in claim 5, wherein the thickness of the first region is 1 μm or more and 2.5 μm or less.

7. The wiring substrate as claimed in claim 6, wherein the thickness of the first region is 1 μm or more and 2 μm or less.

8. The wiring substrate as claimed in claim 1, further comprising:
a connection bump on the insulating layer in an area surrounded by the dam member, the connection bump being partly in an opening in the insulating layer to be electrically connected to the wiring layer.

9. The wiring substrate as claimed in claim 8, further comprising:
a barrier layer on the wiring layer in the opening,
wherein the connection bump is on the barrier layer in the opening.

10. The wiring substrate as claimed in claim 9, wherein the barrier layer includes a nickel plating layer on the wiring layer, a palladium plating layer on the nickel plating layer, and a gold layer on the palladium plating layer.

11. The wiring substrate as claimed in claim 8, further comprising:
a substrate on which the wiring layer is provided and on which the insulating layer is formed to cover the wiring layer,
wherein the wiring layer includes an electrode pad, and
the opening pierces through the insulating layer to reach the electrode pad.

12. The wiring substrate as claimed in claim 1, wherein a mass of the filler accounts for 30% to 70% of a mass of the dam member.

13. The wiring substrate as claimed in claim 1, wherein a thickness of the dam member is 10 μm to 50 μm.

14. The wiring substrate as claimed in claim 1, wherein the resin is at least one of epoxy resin, polyimide resin, or acrylic resin.

15. The wiring substrate as claimed in claim 1, wherein a particle size of the filler is 3 μm to 4 μm.

16. A semiconductor device comprising:
the wiring substrate as set forth in claim 8;
an electronic component electrically connected to the connection bump; and
an underfill provided between the insulating layer and the electronic component.
